(19) United States
(12) Patent Application Publication
(10) Pub. No.: US 2025/0239548 A1
(43) Pub. Date: Jul. 24, 2025

(54) BONDED DEVICE STRUCTURES WITH IMPROVED STRESS DISTRIBUTION AND REDUCED CRACKING AND METHODS OF MAKING THE SAME

(71) Applicant: Taiwan Semiconductor Manufacturing Company Limited, Hsinchu (TW)

(72) Inventors: Yung Lin Tan, Taichung City (TW); Chen-Shien Chen, Zhubei City (TW); Ting Hao Kuo, Hsinchu City (TW); Chih-Sheng Li, Hsinchu City (TW)

(21) Appl. No.: 18/679,828

(22) Filed: May 31, 2024

Related U.S. Application Data
(60) Provisional application No. 63/624,319, filed on Jan. 24, 2024.

(51) Int. Cl. H01L 23/00; H01L 21/304; H01L 21/56; H01L 21/78; H01L 23/31; H01L 23/498; H01L 25/065

(52) U.S. Cl. CPC H01L 24/05; H01L 21/3043; H01L 21/565; H01L 21/78; H01L 23/3121; H01L 24/02; H01L 24/08; H01L 24/80; H01L 25/0657; H01L 23/49838; H01L 25/0652; H01L 2224/02331; H01L 2224/02381; H01L 2224/05008; H01L 2224/05017; H01L 2224/05548; H01L 2224/05557; H01L 2224/08146; H01L 2224/08225; H01L 2224/80345; H01L 2224/80895; H01L 2224/80896; H01L 2224/80948; H01L 2924/1011; H01L 2924/10156; H01L 2924/10157; H01L 2924/3512

(57) ABSTRACT

A bonded device structure includes a carrier structure, an integrated circuit (IC) die bonded to a surface of the carrier structure via a bonding layer, where the IC die includes an eave vertically separated from and overlying the surface of the carrier structure, a bay region is located between the eave and the surface of the carrier structure, and a molding portion is located within the bay region. Various characteristics of the bay region and/or the molding compound may be engineered to provide improved stress distribution and reduce cracking defects. In some embodiments, a ratio of the width to height of the bay region may be >1. In some embodiments, a void ratio of the molding compound may be between 0.2 and 0.4.

### RELATED APPLICATION

This application claims the benefit of priority to U.S. Provisional Patent Application No. 63/624,319 entitled “Novel structure of SoIC oxide films and molding compound” filed on Jan. 24, 2024, the entire contents of which are hereby incorporated by reference for all purposes.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view illustrating a portion of a semiconductor wafer according to various embodiments of the present disclosure.

FIG. 2 is a vertical cross-sectional view of a semiconductor wafer 100 illustrating a plurality of first metal bonding pads and first bonding vias in a first bonding layer according to various embodiments of the present disclosure.

FIG. 3 is a vertical cross-sectional view of a semiconductor wafer illustrating a protective layer located over the upper surface of a first bonding layer according to various embodiments of the present disclosure.

FIG. 4A is a vertical cross-sectional view of a semiconductor wafer illustrating a plurality of openings in a first bonding layer according to various embodiments of the present disclosure.

FIG. 4B is a vertical cross-sectional view of a semiconductor wafer illustrating a plurality of openings in a first bonding layer according to another embodiment of the present disclosure.

FIG. 5 is a vertical cross-section view of a semiconductor wafer following a thinning process to remove a backside portion of a first semiconductor substrate according to various embodiments of the present disclosure.

FIG. 6 is a vertical cross-section view of a semiconductor wafer illustrating a plurality of grooves formed through an interconnect structure according to various embodiments of the present disclosure.

FIG. 7 is a vertical cross-section view of an integrated circuit (IC) die according to various embodiments of the present disclosure.

FIG. 8 is a vertical cross-section view illustrating an IC die bonded to a carrier structure to form a bonded device structure according to various embodiments of the present disclosure.

FIG. 9 is a vertical cross-section view of a bonded device structure including a protective film over exposed surfaces of the bonded device structure 130 according to various embodiments of the present disclosure.

FIG. 10 is a vertical cross-section view of a bonded device structure following a grinding process that removes the protective film from over the backside surface of the first semiconductor substrate of the IC die according to various embodiments of the present disclosure.

FIG. 11 is a vertical cross-section view of a bonded device structure illustrating a molding portion surrounding an IC die according to various embodiments of the present disclosure.

FIG. 12 is a vertical cross-section view of a bonded device structure having a multi-tiered configuration according to various embodiments of the present disclosure.

FIG. 13A is a vertical cross-section view of a bonded device structure having a multi-tiered configuration according to another embodiment of the present disclosure.

FIG. 13B is an enlarged vertical cross-section view of region B of FIG. 13A.

FIG. 13C is an enlarged vertical cross-section view of region C of FIG. 13A.

FIG. 14A is a vertical cross-section view of a bonded device structure having a multi-tiered configuration according to an embodiment of the present disclosure.

FIG. 14B is a top view of the first IC die of the bonded device structure of FIG. 14A.

FIG. 14C is an enlarged vertical cross-section view of region D of FIG. 14A.

FIG. 14D is an enlarged vertical cross-section view of region D of FIG. 14A according to another embodiment of the present disclosure.

FIGS. 15A-15H are vertical cross-section views of multi-tiered bonded device structures illustrating different configurations of protective films according to various embodiments of the present disclosure.

FIGS. 16A-16I are vertical cross-section views of bonded device structures illustrating different shapes of the bay regions underlying the eaves according to various embodiments of the present disclosure.

FIGS. 17A-17I are vertical cross-section views of multi-tiered bonded device structures illustrating various configurations of the shapes of the bay regions for the IC dies in different tiers according to various embodiments of the present disclosure.

FIGS. 18A-18D are top views of bonded device structures according to various embodiments of the present disclosure.

FIG. 18E is a vertical cross-section view of the bonded device structure of FIG. 18A taken along line E-E′ in FIG. 18A.

FIG. 19 is a flowchart illustrating a method of fabricating a bonded device structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and specifically to bonded device structures that include at least one semiconductor integrated circuit (IC) die bonded to a carrier structure, which may be, for example, a substrate, an interposer, another semiconductor die or a semiconductor wafer. The at least one semiconductor IC die may be bonded to the carrier structure in a configuration such as a system on integrated chip (SoIC), chip on wafer on substrate (CoWoS), chip on wafer (CoW), etc. Such bonded device structures may increase the density of devices that may occupy a given planar area or “footprint.”

Semiconductor IC dies may include a semiconductor material substrate, such as a silicon substrate, having a number of circuit components and elements formed on and/or within the semiconductor material. Semiconductor dies are typically fabricated by sequentially depositing insulating or dielectric layers, conductive layers, and semiconductive layers of material over a semiconductor substrate (e.g., a wafer), patterning the various material layers using lithography to form integrated circuits, and separating individual dies from the substrate such as by sawing between the integrated circuits along scribe lines.

A bonded device structure may be formed by placing a first device structure (e.g., an IC die) onto a carrier structure in a “face down” configuration such that integrated circuit components formed on a first (i.e., front) side of a semiconductor substrate of the first device structure face towards a surface of the carrier structure. A bonding process may be used to bond bonding features on the first device structure to corresponding bonding features on the carrier structure.

In some cases, a bonded device structure may include multiple levels, or “tiers,” of device structures. For example, a first IC die may be bonded to a carrier structure, as described above. A second IC die may then be bonded over the second (i.e., back) side of the first IC die, a third IC die may be bonded over the second IC die, and so forth, to provide a multi-tiered bonded device structure.

In some embodiments, a direct bonding technique, such as metal-to-metal (M-M) and dielectric-to-dielectric (D-D) bonding techniques, may be used to bond the device structures to form the bonded device structure. In such bonding techniques, bonding layers including an array of metal bonding pads surrounded by a dielectric material may be formed on the structures to be bonded. The bonding layer on the first device structure may be aligned over the corresponding bonding layer on the second device structure, and the two bonding layers may be brought into contact with one another. This may result in a chemical pre-bond between the dielectric material of the respective bonding layers. An annealing process may then be performed to promote bonding of the metal bonding pads of the respective bonding layers, thereby producing metal bonds extending between the first device structure and the second device structure. Following the bonding process, a molding portion may be provided to encapsulate and protect the various device structures.

One issue with bonded device structures that utilize the bonding techniques as described above is that mechanical stresses can become concentrated in certain regions of the structure. These mechanical stresses may result in poor adhesion of the molding portion, cracks forming in the IC die(s), and other defects. This may negatively affect device performance and yield.

Various embodiments disclosed herein are directed to bonded device structures that may provide improved performance and yield by providing more effective stress distribution and reduced cracking defects. In various embodiments disclosed herein, a bonded device structure may include a carrier structure, an integrated circuit (IC) die bonded to a surface of the carrier structure via a bonding layer, where the IC die includes an eave vertically separated from and overlying the surface of the carrier structure. A bay region may be located between the cave and the surface of the carrier structure, and a molding portion may be located within the bay region. In various embodiments, engineering various characteristics of the bay region, such as the size, shape and/or relative dimensions of the bay region, may enable stress to be more effectively distributed, which may result in reduced crack formation and may improve the overall performance and yields of the bonded device structures.

In some embodiments, the IC die may be formed such that in instances in which the IC die is bonded to the carrier structure, the aspect ratio of the bay region, which may be defined as the ratio of the width dimension to the height dimension of the bay region, may be equal to or greater than 1, such as between 1 and 80. By implementing such a ratio the IC die may facilitate effective stress distribution, which may help improve the performance of the bonded device structure. In various embodiments disclosed herein, the size, shape and/or relative dimensions of the bay region may be controlled by controlling the process(es) used to fabricate the IC die, which may include a plasma dicing process, a laser grooving process, and/or a mechanical dicing process.

In further embodiments, the molding portion may have a void ratio, which may be defined as the total volume of void regions in the molding portion to the total volume of molding compound in the molding portion, that is between 0.2 and 0.4. By implementing such a void ratio, the various embodiments may enable the molding portion to provide adequate mechanical support and/or protection for the various components of the bonded device structure while also enabling sufficient adherence of the molding portion to the surrounding structures.

In some embodiments, one or more protective layers may be provided over surfaces of the IC die to help inhibit crack defects.

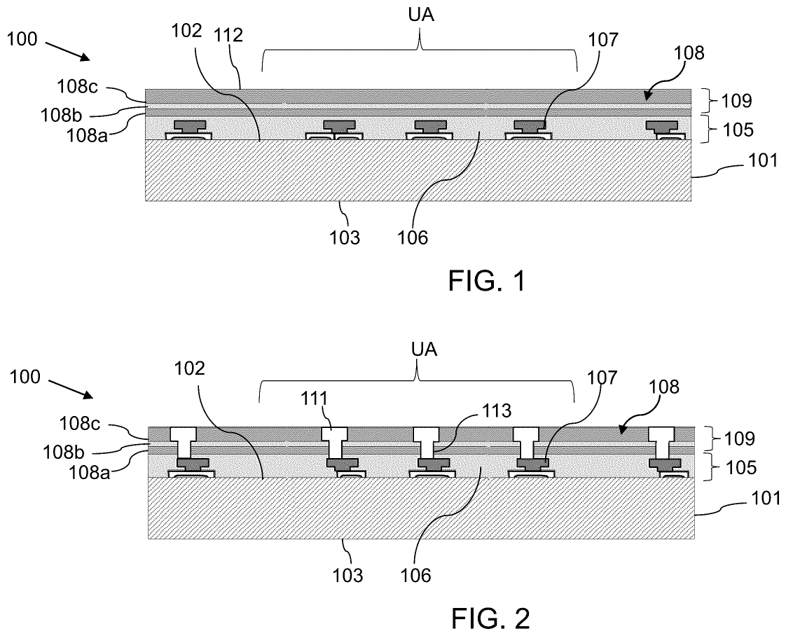

FIGS. 1-11 are sequential vertical cross-sectional views illustrating the intermediate structures during a process of fabricating a bonded device structure according to various embodiments of the present disclosure. FIG. 1 is a vertical cross-sectional view illustrating a portion of a semiconductor wafer 100 according to various embodiments of the present disclosure. The semiconductor wafer 100 may include a first semiconductor substrate 101 that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the first semiconductor substrate 101 may be a semiconductor-on-insulator (SOI) substrate.

The first semiconductor substrate 101 may include a first major surface (i.e., a front side surface 102) and a second major surface (i.e., a backside surface 103). In some embodiments, a thickness of the first semiconductor substrate 101 between the front side surface 102 and the backside surface 103 may be between about 100 μm and about 800 μm, although a first semiconductor substrate 101 having a greater or lesser thickness may also be utilized.

In some embodiments, a plurality of devices (not shown in FIG. 1) may be disposed on, over and/or in the front side surface 102 of the first semiconductor substrate 101. The devices may include, for example, active devices, passive devices, or a combination thereof. In some embodiments, the devices disposed on, over and/or in the front side surface 102 of the first semiconductor substrate 101 may include integrated circuit devices. The integrated circuit devices may include, for example, transistors (e.g., field-effect transistors (FETs)), capacitors, resistors, diodes, photodiodes, fuse devices, or other similar devices. In some embodiments, the integrated circuit devices may include gate electrodes, source/drain regions, spacers, isolation trenches, and the like.

The semiconductor wafer 100 may additionally include an interconnect structure 105 over the front side surface 102 of the first semiconductor substrate 101. The interconnect structure 105 may include metal features 107 (e.g., metal lines, vias, etc.) formed within a dielectric material 106 (e.g., one or more inter-layer dielectric (ILD) layers and/or inter-metal dielectric (IMD) layers) that may provide connections to and/or between various devices located on, over and/or in the front side surface 102 of the first semiconductor substrate 101.

The semiconductor wafer 100 may further include a first bonding layer 109 over the interconnect structure 105 according to various embodiments of the present disclosure. The first bonding layer 109 may include one or more dielectric material layers 108 composed of suitable dielectric material(s), such as silicon oxide, silicon nitride, silicon carbide, silicon carbon nitride, silicon oxynitride, a dielectric polymer material, or the like. Other suitable dielectric materials are within the contemplated scope of disclosure. In one non-limiting embodiment, the one or more first bonding layer 109 may include two or more dielectric material layers 108 having different compositions, where the etch resistivities of the different dielectric layers 108 may be different with respect to an etch chemistry used during a subsequent etching step. Thus, one or more of the dielectric material layers 108 may be referred to as an etch stop layer. In various embodiments, the one or more dielectric material layers 108 may be deposited using any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like, including various combinations thereof. The first bonding layer 109 may have a planar upper surface 112, as shown in FIG. 1.

FIG. 1 illustrates a unit area (UA) of the semiconductor wafer 100. The UA of the semiconductor wafer 100 may be a portion of the semiconductor wafer 100 that may be subsequently separated (i.e., singulated) from the remainder of the semiconductor wafer 100 to provide an integrated circuit (IC) die, as described further below. The UA may include a set of integrated circuit devices disposed on, over and/or in the front side surface 102 of the first semiconductor substrate 101, an interconnect structure 105 over the front side surface 102 of the first semiconductor substrate 101, and a portion of the first bonding layer 109. A semiconductor wafer 100 may typically include a plurality of UAs that may each be separated from the semiconductor wafer 100 to form respective IC dies.

FIG. 2 is a vertical cross-sectional view of the semiconductor wafer 100 illustrating a plurality of first metal bonding pads 111 and first bonding vias 113 in the first bonding layer 109 according to various embodiments of the present disclosure. FIG. 2 illustrates an embodiment including three dielectric material layers, including a first dielectric material layer 108a over the interconnect structure 105, a second dielectric material layer 108b over the first dielectric material layer 108a, and a third dielectric material layer 108c over the second dielectric material layer 108b. However, it will be understood that more or less than three dielectric material layers 108a, 108b and 108c may be utilized. The first dielectric material layer 108a, second dielectric material layer 108b, and third dielectric material layer 108c as shown in FIG. 2 may include suitable dielectric material(s) as described above. The first dielectric material layer 108a, second dielectric material layer 108b, and third dielectric material layer 108c may have the same composition or may have different compositions. In one non-limiting embodiment, the first dielectric material layer 108a and the third dielectric material layer 108c may have the same composition, and the second dielectric material layer 108b may have a different composition. The second dielectric material layer 108b may be an above-described etch stop layer.

Referring to FIG. 2, the first metal bonding pads 111 and the first bonding vias 113 may be formed by forming a plurality of openings in the one or more dielectric material layers 108 of the first bonding layer 109 and depositing a metal material within the openings, such as via a damascene or dual-damascene process. This may include, for example, performing one or more etching processes through a lithographically-patterned mask to form openings in the one or more dielectric material layers 108, and depositing a suitable metal material within the openings to form the first metal bonding pads 111 and/or the first bonding vias 113. An optional planarization process may be used to remove excess conductive material from over the planar upper surface 112 of the first bonding layer 109. The first metal bonding pads 111 and the first bonding vias 113 may include a suitable conductive material, such as copper (Cu), tungsten (W), aluminum (Al), and the like. The first metal bonding pads 111 and the first bonding vias 113 may be formed using a suitable deposition process, such as, for example, physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof.

Referring again to FIG. 2, the plurality of first metal bonding pads 111 may be laterally surrounded by the dielectric material layer(s) 108 of the first bonding layer 109. At least some of the first metal bonding pads 111 may be electrically coupled to underlying metal features 107 of the interconnect structure 105 via a first bonding via 113.

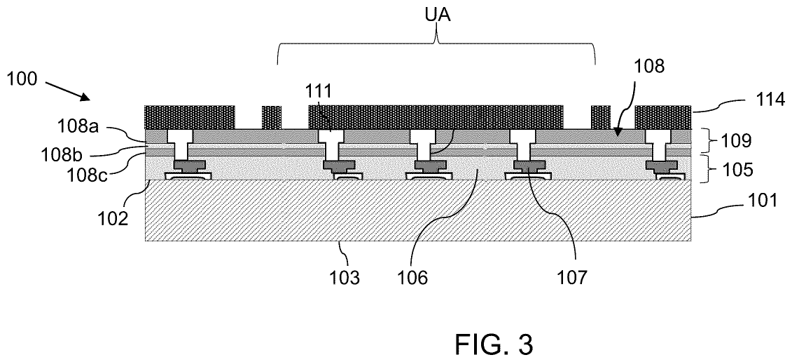

FIG. 3 is a vertical cross-sectional view of the semiconductor wafer 100 illustrating a protective layer 114 located over the upper surface of the first bonding layer 109 according to various embodiments of the present disclosure. Referring to FIG. 3, the protective layer 114 may be configured to protect select regions of the semiconductor wafer 100 from damage during a subsequent plasma dicing step to be described further below. The protective layer 114 may be patterned such that the protective layer 114 may cover the central regions of the unit areas (UAs) and may include openings through the protective layer 114 near the periphery of the UAs. The protective layer 114 may be deposited as a continuous layer over the first metal bonding pads 111 and the first bonding layer 109 and may be patterned to form the plurality of openings through the protective layer 114. In some embodiments, the protective layer 114 may be composed of a polymer-based material, such as a photosensitive material (e.g., a photoresist material) that may be patterned using photolithographic techniques. Other suitable materials may be utilized for the protective layer 114.

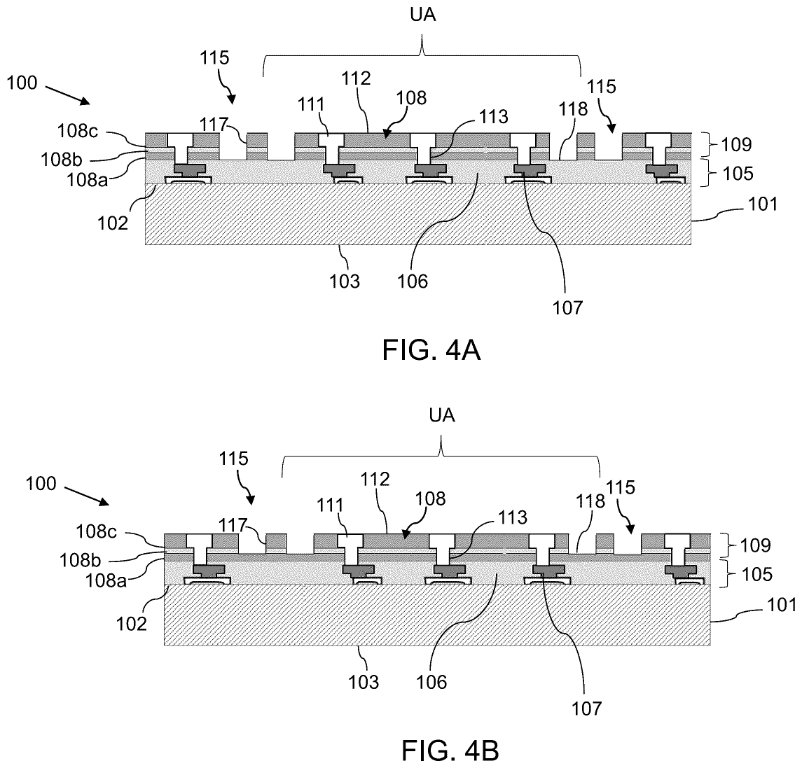

FIG. 4A is a vertical cross-sectional view of the semiconductor wafer 100 illustrating a plurality of openings 115 in the first bonding layer 109 according to various embodiments of the present disclosure. Referring to FIG. 4A, in various embodiments, a plasma dicing process may be used to remove portions of the one or more dielectric material layers 108 of the first bonding layer 109 that are exposed through openings in the protective layer 114. The openings 115 may function as dicing lanes or “streets” that may extend around the periphery of the unit areas (UAs) of the semiconductor wafer 100. Plasma dicing is a dry etching process that uses plasma to selectively etch away a target material. In one non-limiting embodiment, the plasma dicing process may include a pulsed or time-multiplexed process that alternates between an isotropic etching process (e.g., using a sulfur hexafluoride (SF₆) plasma) and the deposition of a thin passivation layer (e.g., using an octafluorocyclobutane (C₄F₈)) plasma) over the etched surfaces. During the subsequent etching process, directional ions attack and remove the passivation layer and the underlying material from surfaces perpendicular to the incident ions while the passivation layer protects sidewall surfaces from being etched. Repeating these etching and deposition steps over a number of iterations may provide a highly-directional etch that may produce steep, nearly vertical sidewalls. Following the plasma etching process, the protective layer 114 may be removed using a suitable process, such as by ashing or dissolution using a solvent.

In various embodiments, plasma dicing may enable shorter process times, reduced device damage and lower particle generation than other similar technologies, such as mechanical blade and/or laser dicing processes. In addition, plasma dicing may enable improved precision and control of the size and shape of the openings 115 formed in the first bonding layer 109. Referring again to FIG. 4, the openings 115 formed by the plasma dicing process may have a trench-like shape including a recessed surface 118 and an interior sidewall 117 extending between the recessed surface 118 and the planar upper surface 112 of the first bonding layer 109. Various parameters of the plasma etching process, such as the plasma power, the particular plasma gas(es) utilized, the etch selectivity of the material(s) of the first bonding layer 109, the size and locations of the openings through the protective layer 114, etc. may be selected and controlled to control the size and shapes of the openings 115. As discussed in further detail below, controlling the size and shape of the openings 115 may help to improve stress distribution and reduce cracking defects in a bonded device structure to be subsequently formed.

Although FIG. 4A illustrates the openings 115 extending through the first bonding layer 109 to the dielectric material 106 of the interconnect structure 105, it will be understood that in other embodiments, the openings 115 may not extend completely through the first bonding layer 109, or the openings 115 may extend into the dielectric material 106 of the interconnect structure 105 and/or into the first semiconductor substrate 101. FIG. 4B is a vertical cross-section view of the semiconductor wafer 100 according to another embodiment in which the openings 115 extend through the third dielectric material layer 108c and the second dielectric material layer 108b and expose the first dielectric material layer 108a of the first bonding layer 109.

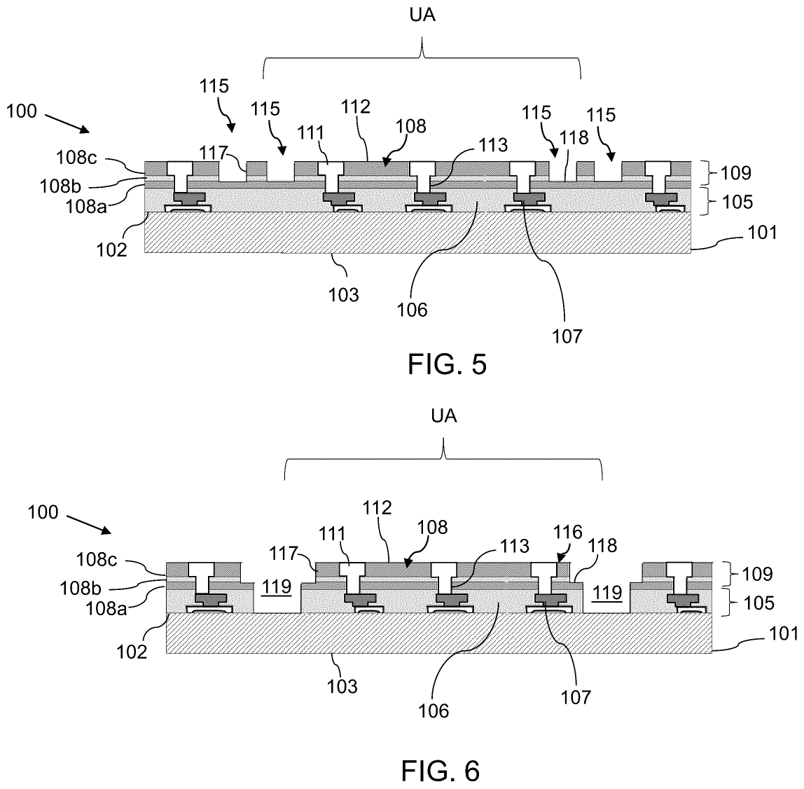

FIG. 5 is a vertical cross-section view of the semiconductor wafer 100 following a thinning process to remove a backside portion of the first semiconductor substrate 101 according to various embodiments of the present disclosure. Referring to FIG. 5, in some embodiments, a thinning process may be performed to remove a backside portion of the first semiconductor substrate 101 of the semiconductor wafer 100. The thinning process may include, for example, a grinding process. In various embodiments, grinding equipment may be utilized to mechanically grind the backside surface 103 of the first semiconductor substrate 101 to remove material from the backside of the first semiconductor substrate 101 and reduce the thickness of the first semiconductor substrate 101. In some embodiments, the thinning process on the first semiconductor substrate 101 may expose one or more conductive via structures (e.g., through-substrate vias (TSVs), not shown in FIG. 5) in the backside surface 103 of the first semiconductor substrate 101. FIG. 5 illustrates an embodiment in which the openings 115 through the first bonding layer 109 extend partially through the first bonding layer (i.e., through the third dielectric material layer 108c and the second dielectric material layer 108b), as shown in FIG. 4B, although it will be understood that in other embodiments, the openings 115 may extend through the entire first bonding layer 109, as shown in FIG. 4A.

FIG. 6 is a vertical cross-section view of the semiconductor wafer 100 illustrating a plurality of grooves 119 formed through the interconnect structure 105 according to various embodiments of the present disclosure. Referring to FIG. 6, a laser grooving process may be performed to remove portions of the interconnect structure 105, including the dielectric material 106 and any metal features 107, from around the periphery of the unit areas (UAs). A laser grooving process may include directing a high-energy laser beam at select regions of the semiconductor wafer 100, resulting in localized heating and vaporization of the irradiated regions. This may result in the formation of localized trenches or grooves 119 as shown in FIG. 6. The grooves 119 may extend through the entire interconnect structure 105 such that the first semiconductor substrate 101 may be exposed at the bottom of the grooves 119. In some embodiments, the grooves 119 may further extend partially into the first semiconductor substrate 101. The grooves 119 may laterally surround each of the UAs of the semiconductor wafer 100. The laser grooving process may “precut” the individual UAs prior to performing a final dicing process through the entire thickness of the first semiconductor substrate 101 to form individual IC dies. Performing a precut of the UAs prior to final dicing may enable a cleaner dicing process with fewer sawing defects.

Referring again to FIG. 6, the laser grooving process may be performed between neighboring pairs of openings 115 in the semiconductor wafer 100. The laser grooving process may remove the portion of the first bonding layer 109 that is located between each neighboring pair of openings 115 and that defines one of the sidewalls 117 of the respective opening 115. The laser grooving process may thus remove one of the sidewalls 117 of each of the openings 115. The grooves 119 formed via the laser grooving process may be offset from the remaining sidewall 117 of each of the above-described openings 115 within each UA. Thus, following the laser grooving process, at least a portion of the recessed surfaces 118 of the openings 115 may remain between the grooves 119 and the remaining sidewalls 117 of the openings 115. Each UA may include a mesa structure 116 including a planar upper surface 112 and sidewalls 117 extending between the planar upper surface 112 and the recessed surface 118. The recessed surface 118 may laterally surround the mesa structure 116 and may extend between the mesa structure 116 the grooves 119 surrounding the periphery of the UA.

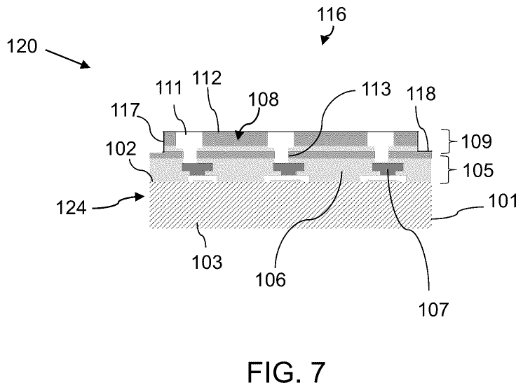

FIG. 7 is a vertical cross-section view of an integrated circuit (IC) die 120 according to various embodiments of the present disclosure. Referring to FIG. 7, the semiconductor wafer 100 may be subjected to a dicing process. In various embodiments, the dicing process may be a mechanical dicing process that utilizes a blade, such as a diamond or carbide blade, to cut (e.g., saw) through the semiconductor wafer 100, including through the first semiconductor wafer 100. The dicing may occur along the precut grooves 119 described above such that individual UAs may be separated from the semiconductor wafer 100 to provide IC dies 120 as shown in FIG. 7. Each of the IC dies 120 may include side surfaces 124 extending between the backside surface 103 of the first semiconductor substrate 101 and the recessed surface 118, and a mesa structure 116 including a planar upper surface 112 and sidewalls 117 extending between the planar upper surface 112 and the recessed surface 118.

Referring again to FIG. 7, the IC die 120 may include any type of die, including a functional die (e.g., a logic die, a memory die, an analog die, an RF die, an integrated passive device (IPD) die, etc., including various combinations thereof). In other embodiments, the IC die 120 may be a non-functional or “dummy” die that may include, for example, metal interconnect structures over a semiconductor substrate that may be used for routing signals within a bonded device structure to be subsequently formed.

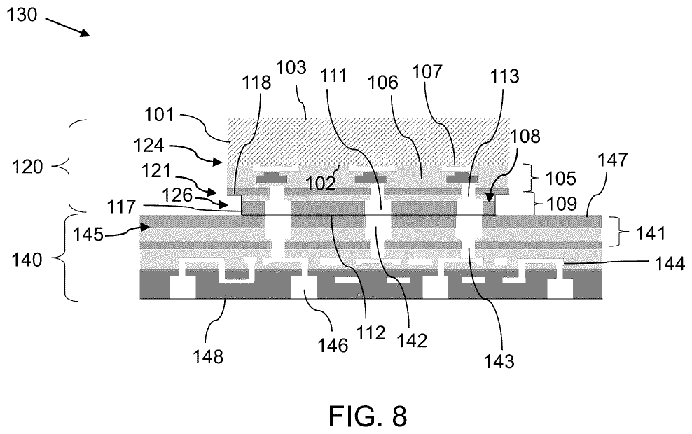

FIG. 8 is a vertical cross-section view illustrating an IC die 120 bonded to a carrier structure 140 to form a bonded device structure 130 according to various embodiments of the present disclosure. Referring to FIG. 8, the IC die 120 may be inverted (i.e., flipped over) relative to its orientation as shown in FIG. 7 such that the planar upper surface 112 of the first bonding layer 109 faces downwards and the backside surface 103 of the first semiconductor substrate 101 faces upwards. The IC die 120 may be aligned over a carrier structure 140. The carrier structure 140 may include, for example, another IC die, a semiconductor wafer, an interposer, and/or a substrate (e.g., a semiconductor, a glass, or an organic substrate) that may be configured to support the IC die 120. The carrier structure 140 may include a first surface 147 (i.e., a frontside surface 147) facing the IC die 120 and a second surface 148 (i.e., a backside surface 148) opposite the first surface 147. In the embodiment shown in FIG. 8, the carrier structure 140 may include metal interconnect features 144 extending through a thickness of the carrier structure 140. The metal interconnect features 144 may be electrically coupled to bonding structures 146 (e.g., bonding pads) on the backside surface 148 of the carrier structure 140. The bonding structures 146 may enable the bonded device structure 140 to be bonded to another support structure, such as a package substrate or a printed circuit board (PCB), such as via solder connections.

The carrier structure 140 may additionally include a second bonding layer 141. The second bonding layer 141 may be similar to the first bonding layer 109 described above. In particular, the second bonding layer 141 may include one or more dielectric material layers 145 composed of suitable dielectric material(s) as described above. The upper surface of the uppermost dielectric material layer 145 of the second bonding layer 141 may form the front side surface 147 of the carrier structure 140. A plurality of second metal bonding pads 142 may be formed within the dielectric material layer(s) 145 of the second bonding layer 141. Each of the second metal bonding pads 142 may be laterally surrounded by the dielectric material layer(s) 145. Upper surfaces of the second metal bonding pads 142 may be exposed on the frontside surface 147 of the carrier structure 140. At least some of the second metal bonding pads 142 may be electrically coupled to underlying metal interconnect features 144 of the carrier structure via a second bonding via 143.

The layout of the second metal bonding pads 142 of the second bonding layer 141 may correspond to the layout of the first metal bonding pads 111 of the first bonding layer 109. The IC die 120 may be aligned over the carrier structure 140 such that each first metal bonding pad 111 of the first bonding layer 109 may be aligned with a corresponding second metal bonding pad 142 of the second bonding layer 141.

Referring again to FIG. 8, in various embodiments, the first bonding layer 109 may be bonded to the second bonding layer 141 via a metal-to-metal (M-M) and dielectric-to-dielectric (D-D) direct bonding technique to couple the IC die 120 mechanically and electrically to the carrier structure 140. In some embodiments, prior to bonding the IC die 120 to the carrier structure 140, the surfaces of the first bonding layer 109 on the IC die 120 and/or the second bonding layer 141 on the carrier structure 140 may optionally be subjected to a pre-treatment process (e.g., a plasma treatment process) to promote surface activation of the first bonding layer 109 and/or the second bonding layer 141 prior to bonding the IC die 120 to the carrier structure 140. To perform the bonding process, the IC die 120 and the carrier structure 140 may be brought together such that the first bonding layer 109 of the IC die 120 contacts the second bonding layer 141 of the carrier structure 140. The IC die 120 and the carrier structure 140 may be aligned such that first metal bonding pads 111 of the first bonding layer 109 contact corresponding second metal bonding pads 142 of the second bonding layer 141 and dielectric material of the first bonding layer 109 contacts dielectric material of the second bonding layer 141. In a direct bonding process, such as a metal-to-metal (M-M) and dielectric-to-dielectric (D-D) bonding process, bringing the first bonding layer 109 and the second bonding layer 141 into contact with one another may result in a pre-bonding process in which chemical bonds (e.g., hydrogen bridge bonds) may form at the planar interface between the dielectric material of the first bonding layer 109 and the dielectric material of the second bonding layer 141. In some embodiments, the pre-bonding process may be performed at ambient temperature (e.g., ˜20° C.). In other embodiments, the pre-bonding process may be performed at an elevated temperature. In some embodiments, a compressive force may be applied to the IC die 120 and the carrier structure 140 during the pre-bonding process. In other embodiments, no compressive force may be applied during the pre-bonding process.

Referring again to FIG. 8, in some embodiments, an annealing process may be performed to complete the bonding of the first metal bonding pads 111 of the first bonding layer 109 to the second metal bonding pads 142 of the second bonding layer 141 according to various embodiments of the present disclosure. The annealing process may be performed at an elevated temperature, such as 100° C. or more, such as between about 150° C. and about 350° C., although lower and higher temperatures may also be utilized. In some embodiments, a compressive force may be applied to the IC die 120 and the carrier structure 140 during the annealing process. In other embodiments, no compressive force may be applied during the annealing process.

Following the bonding process, the bonded device structure 130 may include an IC die 120 that is mechanically and electronically coupled to an underlying carrier structure 140. As shown in FIG. 8, the planar upper surface 112 of the mesa structure 116 of the IC die 120 (see FIG. 7) may contact and may be bonded to the front side surface 147 of the carrier structure 140. The recessed surface 118 of the IC die 120 (see FIG. 7) may be vertically offset from the front side surface 147 of the carrier structure 140. As shown in FIG. 8, portions of the IC die 120 around the periphery of the IC die 120 may overhang the front side surface 147 of the carrier structure 140. A portion of the IC die 120 overhanging the front side surface 147 of the carrier structure 140 may be referred to as an “eave” 121. The space underlying the eave 121 located between the recessed surface 118, the sidewall surface 117 of the mesa structure 116, and the surface to which the IC die 120 is mounted (i.e., the frontside surface 147 of the carrier structure 140 in FIG. 8) may be referred to as a “bay” region 126. Controlling various characteristics of the bay region 126 underlying the eave 121, such as the size and shape of the bay region 126, may help to improve stress distribution, reduce cracking defects, and promote adhesion of one or more protective films over exposed surfaces of the bonded device structure 130, as described in further detail below.

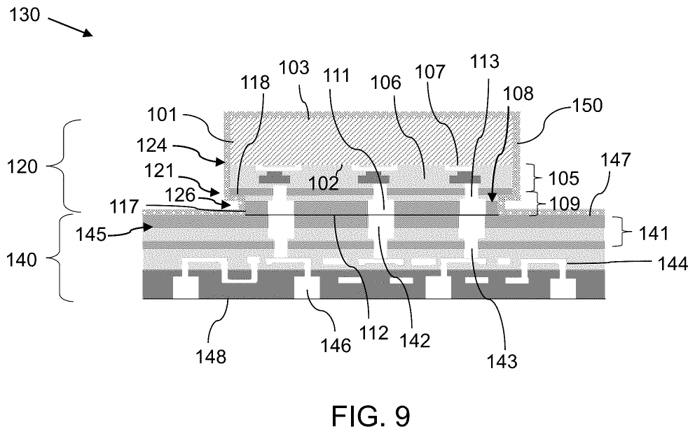

FIG. 9 is a vertical cross-section view of a bonded device structure 130 including a protective film 150 over exposed surfaces of the bonded device structure 130 according to various embodiments of the present disclosure. Referring to FIG. 9, at least one protective film 150 may be conformally deposited over exposed surfaces of the bonded device structure 130, including the front side surface 147 of the carrier structure 140, the side surfaces 124 of the IC die 120, the backside surface 103 of the first semiconductor substrate 101, and over the sidewall surface 117 and the recessed surface 118 within the bay region 126 underlying the eave 121. In various embodiments, the at least one protective film 150 may composed of a suitable dielectric material, such as silicon nitride (SiN), silicon oxynitride (SiON), silicon carbide (SiC), and/or silicon carbon nitride (SiCN). Other suitable materials, including oxide, nitride, and/or carbide materials, may be utilized for the at least one protective film 150. The at least one protective film 150 may be deposited using a suitable deposition method as described above.

Although FIG. 9 illustrates the at least one protective film 150 deposited over a bonded device structure 130 including an IC die 120 bonded to a carrier structure 140, in other embodiments, at least one protective film 150 may be deposited over the IC die 120 before the IC die 120 is bonded to a carrier structure 140 to form a bonded device structure 130. In such embodiments, the first bonding layer 109 may be masked to prevent the at least one protective film 150 from being deposited over the planar upper surface 112 of the first bonding layer 109 that subsequently bonded to the carrier structure 140. Alternatively, the at least one protective film 150 may be deposited over all exposed surfaces of the IC die 120 and removed from select surfaces (such as planar upper surface 112) via etching or another suitable process.

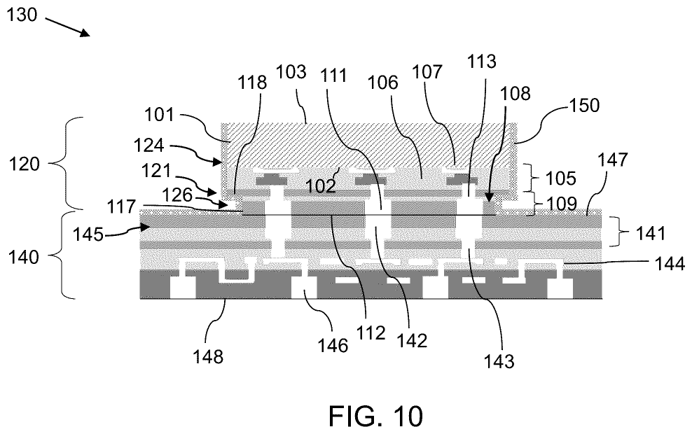

FIG. 10 is a vertical cross-section view of a bonded device structure 130 following a grinding process that removes the protective film 150 from over the backside surface 103 of the first semiconductor substrate 101 of the IC die 120 according to various embodiments of the present disclosure. Referring to FIG. 10, an optional mechanical grinding process may be performed to remove the at least one protective film 150 from over the backside surface 103 of the first semiconductor substrate 101. Following the grinding process, the at least one protective film 150 may remain over the front side surface 147 of the carrier structure 140, the side surfaces 124 of the IC die 120, and in the bay region 126. In other embodiments, the grinding step may be omitted and the at least one protective film 150 may remain over the backside surface 103 of the first semiconductor substrate 101 of the IC die 120.

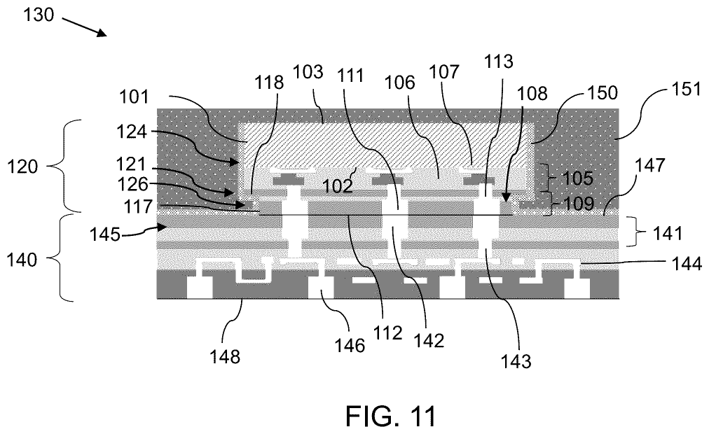

FIG. 11 is a vertical cross-section view of a bonded device structure 130 illustrating a molding portion 151 surrounding the IC die 120 according to various embodiments of the present disclosure. Referring to FIG. 11, a molding portion 151 may be formed over the front side surface 147 of the carrier structure 140, over the backside surface 103 of the first semiconductor substrate 101, over the side surfaces 124 of the IC die 120 and within the bay region 126 underlying the eave 121. In locations where at least one protective film 150 exists, the molding portion 151 may be formed over and may contact the at least one protective film 150. In various embodiments, the molding portion 151 may include an epoxy material. For example, the molding portion 151 may include an epoxy mold compound (EMC) that may include epoxy resin, a hardener (i.e., a curing agent), silica or other filler material(s), and optionally additional additives. The EMC may be applied around the periphery of the IC die 120 in liquid or solid form, and may be hardened (i.e., cured) to form a molding portion 151 having sufficient stiffness and mechanical strength surrounding the IC die 120. Although FIG. 11 illustrates the molding portion 151 located over the backside surface 103 of the first semiconductor substrate 101. In other embodiments, portions of the molding portion 151 that extend above a horizontal plane including the backside surface 103 of the first semiconductor substrate 101 may be removed using a planarization process, such as a chemical mechanical planarization (CMP) process.

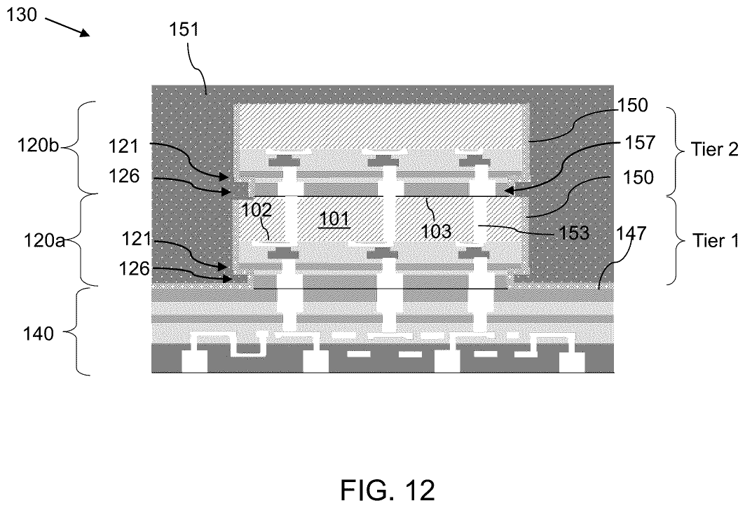

FIG. 12 is a vertical cross-section view of a bonded device structure 130 having a multi-tiered configuration according to various embodiments of the present disclosure. Referring to FIG. 12, the bonded device structure 130 includes a first IC die 120a bonded to the front side surface 147 of the carrier structure 140, and a second IC die 120b located over and bonded to the first IC die 120a. The first IC die 120a and the second IC die 120b may be similar to the IC die 120 described above with reference to FIGS. 8-11. Thus, repeated discussion of like elements is omitted for brevity. The first IC die 120a and the second IC die 120b may be the same type of dies (e.g., logic dies, memory dies, “dummy” dies, etc.) or may be different types of dies. In the embodiment shown in FIG. 12, the front side of the second IC die 120b may be bonded over the backside surface 103 of the first semiconductor substrate 101 of the first IC die 120a in a “front to back” configuration. The second IC die 120b may be bonded to the first IC die 120b via a bond portion 157 that may be formed using an M-M and D-D direct bonding technique as described above. Through-substrate vias 153 (TSVs) may extend through the first semiconductor substrate 101 and may be used to transmit signals between the second semiconductor IC die 120b and devices and/or interconnect features located over the front side surface 102 of the first semiconductor substrate 101. Both the first IC die 120a and the second IC die 120b may include eaves 121 with bay regions 126 underlying the eaves 121. In the case of the second IC die 120b, the eaves 121 may include portions of the second IC die 120b that overhang the first IC die 120a. At least one protective layer 150 may be located over surfaces of the first IC die 120a and the second IC die 120b. A molding portion 151 may laterally surround the first IC die 120a and the second IC die 120b and may extend within the bay regions 126 underlying the eaves 121.

In various embodiments, IC dies 120 mounted directly to the front side surface 147 of the carrier structure 140 may be referred to as a first tier of IC dies 120. Additional IC dies 120 mounted over the IC dies 120 of the first tier may be referred to as a second tier of IC dies 120, and so forth. Although the embodiment shown in FIG. 12 includes two tiers of IC dies 120 over the carrier structure 140, it will be understood that a bonded device structure 130 according to various embodiments may have N tiers, where Nis an integer number that is ≥1 (i.e., N=1, 2, 3, 4 . . . ).

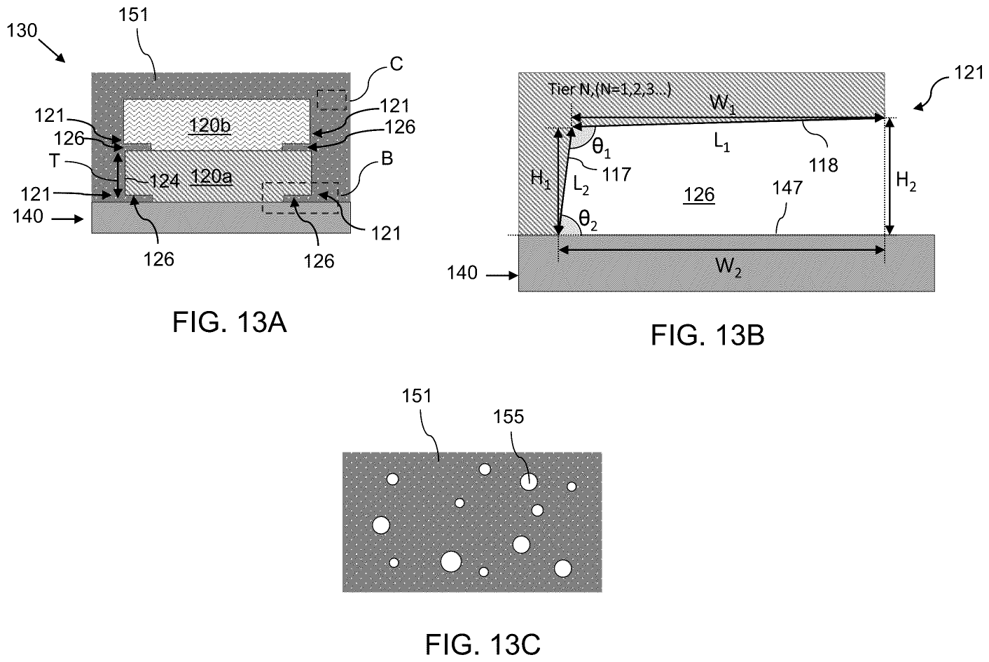

FIG. 13A is a vertical cross-section view of a bonded device structure 130 having a multi-tiered configuration according to another embodiment of the present disclosure. FIG. 13B is an enlarged vertical cross-section view of region B of FIG. 13A. FIG. 13C is an enlarged vertical cross-section view of region C of FIG. 13A. Referring to FIG. 13A, the bonded device structure 130 of FIG. 13A is similar to the bonded device structure 130 described above with reference to FIG. 12. Thus, repeated discussion of like elements is omitted for brevity. The bonded device structure 130 of FIG. 13A does not include an above-described protective film 150, but is otherwise equivalent to the bonded device structure 130 of FIG. 12.

FIG. 13B is an enlarged vertical cross-section view of region B of FIG. 13A illustrating an eave 121 and the bay region 126 underlying the eave 121. For clarity of illustration, the molding portion 151 is not shown in FIG. 13B. As mentioned above, various characteristics of the bay regions 126 underlying the eaves 121 of the IC dies 120 may be engineered to provide improved device yields and performance.

Referring to FIG. 13B, a width dimension, W, of the bay region 126 may be defined as W₁*0.5+W₂*0.5, where W₁ is the horizontal width of the eave 121 which defines the top surface of the bay region 126, and W₂ is the horizontal width of the bay region 126 on the bottom surface of the bay region 126. Similarly, a height dimension, H, of the bay region 126 may be defined as H₁*0.5+H₂*0.5, where H₁ is the vertical inner height of the bay region 126 on the inner side of the bay region 126 (i.e., the side of the bay region 126 adjacent to the interior sidewall 117 in FIG. 13B), and H₂ is the vertical outer height of the bay region 126 on the outer side of the bay region 126 (i.e., the side of the bay region 126 defined by the peripheral edge of the eave 121). Put another way, the width dimension, W, may be defined as the average of the horizontal width dimensions of the bay region 126 along the top and bottom surfaces of the bay region 126 (i.e., (W₁+W₂)/2), and the height dimension, H, may be defined as the average of the vertical height dimensions of the bay region 126 on the inner and outer sides of the bay region 126 (i.e., (H₁+H₂)/2). An aspect ratio of the bay region 126 may be defined as the width divided by height, or W/H. The aspect ratio of the bay region 126 may be controlled during the above-described plasma dicing, laser grooving and dicing processes used to form the IC dies 120. In various embodiments, the aspect ratio of the bay region 126 may be ≥1, such as ≥1 and ≤80. An aspect ratio within this range of 1 to 80 may provide effective stress distribution, bonding of the protective film(s) 150, and minimize cracking defects while also enabling sufficient filling of the molding compound. In some embodiments, all of the IC dies 120 of the bonded device structure 130 may include eaves 121 as described above, and the aspect ratio of each of the bay regions 126 underlying the respective eaves may be ≥1 and ≤80.

Referring again to FIG. 13, another characteristic of the eave 121 and the underlying bay region 126 that may be controlled is the angle, θ₁, between the interior sidewall 117 and the top surface 118 of the bay region 126. This angle, θ₁, may be controlled at least in part by controlling parameters of the plasma dicing process used to form the interior sidewall 117 of the mesa structure 116 and the recessed surface 118 of the IC die 120 as described above with reference to FIGS. 4-7. In various embodiments, θ₁ may be at least 10°. In some embodiments, θ₁ may be greater than 10° and less than or equal to 170°. In some embodiments, a value of θ₁ that is ≥10° and ≤170° may provide effective stress distribution, minimize cracking defects while also enabling good bonding of one or more protective films 150 over the surfaces of the bay region 126. In some embodiments, all of the IC dies 120 of the bonded device structure 130 may include eaves 121 as described above, where the angle, θ₁, between the interior sidewall 117 and the top surface 118 of the bay region 126 underlying the respective eaves may be ≥10° and ≤170°.

Another characteristic of the eave 121 and the underlying bay region 126 that may be controlled is the angle, θ₂, between the interior sidewall 117 and the bottom surface 147 of the bay region 126. For IC dies 120 in the first tier of the bonded device structure 130, the bottom surface 147 of the bay region 126 may be the front side surface 147 of the carrier structure 140. For IC dies in higher tiers (i.e., Tier N, where N>2), the bottom surface 147 of the bay region 126 may be an upper surface of the underlying tier (i.e., Tier N−1). This angle, θ₂, may be controlled at least in part by controlling parameters of the plasma dicing process used to form the interior sidewall 117 of the mesa structure 116 as described above with reference to FIGS. 4-7. In various embodiments, θ₂ may be at least 10°. In some embodiments, θ₂ may be greater than 10° and less than or equal to 170°. In some embodiments, a value of θ₂ that is >10° and ≤170° may provide effective stress distribution, minimize cracking defects while also enabling good bonding of one or more protective films 150 over the surfaces of the bay region 126. In some embodiments, all of the IC dies 120 of the bonded device structure 130 may include eaves 121 as described above, where the angle, θ₂, between the interior sidewall 117 and the bottom surface 147 of the bay region 126 underlying the respective eaves may be ≥10° and ≤170°.

Referring again to FIG. 13B, another characteristic that may be controlled is the horizontal width dimension of the eave 121, W₁. The horizontal width dimension of the eave 121, W₁, may be expressed as L₁*cos (θ₁+θ₂−180°), where L₁ is the length of the lower surface of the eave 121 that forms the top surface 118 of the bay region 126. The horizontal width dimension, W₁, of the eaves 121 may be controlled during the above-described plasma dicing, laser grooving and dicing processes used to form the IC dies 120. In various embodiments, the horizontal width of the eave 121, W₁, may be ≤ 100 μm. In some embodiments, a value of W₁ that is ≤100 μm may provide effective stress distribution, minimize cracking defects while also enabling good bonding of one or more protective films 150 over the surfaces of the bay region 126. In cases where the eaves 121 have excessively large horizontal width dimensions, W₁, it may be difficult to fill the bay regions 126 with a molding compound, which may lead to poor reliability of the bonded device structure 130. In some embodiments, all of the IC dies 120 of the bonded device structure 130 may include eaves 121 having horizontal width dimensions, W₁, that are ≤100 μm.

In some embodiments, the horizontal width dimensions, W₁, of the eaves 121 may also be at least partially a function of the thickness of the IC die 120. Referring to FIGS. 13A and 13B, the IC dies 120 may have a thickness dimension, T, along the side surfaces 124 of the IC dies 120. In various embodiments, the horizontal width dimensions, W₁, of the eaves 121 may be <1/100*T. In some embodiments, a width dimension W₁ of the eaves 121 that is less than one-hundredth of the thickness dimension, T, of the IC die 120 may provide effective stress distribution, minimize cracking defects while also enabling good bonding of one or more protective films 150 over the surfaces of the bay region 126. In cases where the eaves 121 have horizontal width dimensions, W₁, that are equal to 1/100 or more of the thickness dimension, T, bonding stresses may be excessively high, which may be bad for bonding. In some embodiments, all of the IC dies 120 of the bonded device structure 130 may include eaves 121 having horizontal width dimensions, W₁, that are <1/100 of the thickness dimensions, T, of the respective IC dies 120.

Referring again to FIG. 13B, another characteristic that may be controlled is the horizontal width dimension of the bottom surface of the bay region 126, W₂. The horizontal width dimension, W₂, of the bottom surface of the bay region 126 may be controlled during the above-described plasma dicing, laser grooving and dicing processes used to form the IC dies 120. In various embodiments, the horizontal width of the bottom surface of the bay region 126, W₂, may be between 0.5 and 1.5 times the above-described horizontal width dimension of the eave 121, W₁. In some embodiments, a value of W₁ that is ≥0.5*W₁ and ≤0.5*W₁ may provide effective stress distribution, minimize cracking defects while also enabling good bonding of one or more protective films 150 over the surfaces of the bay region 126. In some embodiments, all of the IC dies 120 of the bonded device structure 130 may include horizontal width dimensions of the bottom surfaces of the bay regions 126, W₂, that are ≥0.5*W₁ and ≤0.5*W₁.

Referring again to FIGS. 13A and 13B, another characteristic that may be controlled is the vertical inner height dimension, H₁ of the bay region 126. In various embodiments, the vertical inner height dimension, H₁ of the bay region 126 may be less than one-half of the thickness dimension, T, of the IC die 120. In some embodiments, a vertical inner height dimension, H₁, of the bay region 126 that is <0.5*T may provide effective stress distribution, minimize cracking defects while also enabling good bonding of one or more protective films 150 over the surfaces of the bay region 126. In cases where the vertical inner height dimension, H₁, is excessively large in relation to the thickness, T, of the IC die 120, the bonding of the one or more protective films 150 may be poor. In some embodiments, all of the IC dies 120 of the bonded device structure 130 may include bay regions having vertical inner height dimensions, H₁, that are less than one-half of the thickness dimensions, T, of the respective IC dies 120.

In some embodiments, the bay regions 126 may have a minimum vertical inner height dimension, H₁. In some embodiments, the minimum vertical inner height dimension, H₁ may be at least about 1 μm. Alternatively, or in addition, the minimum vertical inner height dimension, H₁ may be at least about 1/200*T. In various embodiments, maintaining the vertical inner height dimension, H₁, at or above a minimum distance may enable the molding compound to adequately fill the bay regions 126 with a molding compound, which improve the reliability of the bonded device structure 130.

FIG. 13C is an enlarged vertical cross-section view of region C of FIG. 13A illustrating the molding portion 151. In some embodiments, characteristics of the molding portion 151 may be engineered to provide improved device yields and performance. One characteristic of the molding portion 151 that may be controlled is the void ratio. Referring to FIG. 13C, the molding portion 151 is generally not a completely solid material, but typically includes void regions 155 within the molding portion 151 that do not include molding compound. The void ratio may be defined as the total volume of the voids 155 divided by the total volume of the solid molding compound within the molding portion 151. The void ratio may be controlled in part by controlling the process conditions used to form the molding portion 151. For example, the void ratio may be controlled, in part, via the selection of the curing temperature and heating rate of the molding process used to form the molding portion 151.

In various embodiments, the void ratio of the molding portion 151 may be between 0.2 and 0.4. A void ratio of the molding portion 151 that is ≥0.2 and ≤0.4 may provide effective mechanical support, good adherence to the surrounding structure(s), reduced stress, and good thermal matching. A molding portion 151 having void ratio that is excessively high may not provide adequate mechanical support and/or protection for the various components of the bonded device structure 130. A molding portion 151 having void ratio that is excessively low may be too dense, which may result in large coefficient of thermal expansion (CTE) mismatch with the surrounding structures that can lead to poor adhesion of the molding portion 151.

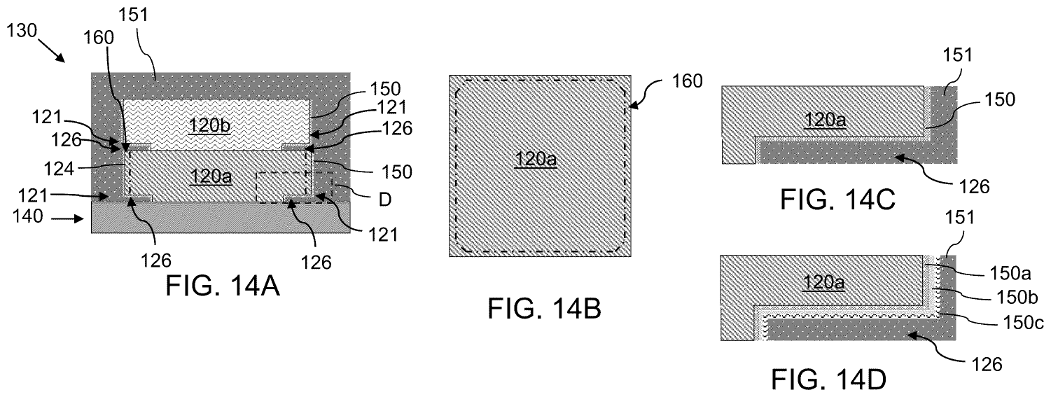

FIG. 14A is a vertical cross-section view of a bonded device structure 130 having a multi-tiered configuration according to an embodiment of the present disclosure. FIG. 14B is a top view of the first IC die 120a of the bonded device structure 130 of FIG. 14A. FIG. 14C is an enlarged vertical cross-section view of region D of FIG. 14A. FIG. 14D is an enlarged vertical cross-section view of region D of FIG. 14A according to another embodiment of the present disclosure. Referring to FIG. 14A, the bonded device structure 130 of FIG. 14A is similar to the bonded device structures 130 described above with reference to FIGS. 12 and 13A. Thus, repeated discussion of like elements is omitted for brevity. The bonded device structure 130 of FIG. 14A includes an above-described protective film 150 located over the side surfaces 124 and within the bay regions 126 underlying the eaves 121 in each of the IC dies 120a and 120b. Providing at least one protection film 150 over surfaces of the IC dies 120 may help to improve adhesion between the molding portion 151 and the IC dies 120 and may also help to reduce thermal stresses, which can result in unwanted crack formation. As noted above, suitable materials for the at least one protection film 150 may include, for example, SiO, SiN, SiON, SiC, SiCN, etc. Other suitable materials for the at least one protection film 150 may also be utilized. A single protection film 150 may be utilized, or as described in further detail below, multiple protection films 150 may be located over select surfaces of the IC dies 120. The multiple protection films 150 may have the same composition, or different protection films 150 may have different compositions.

FIG. 14B is a top view of the first IC die 120a. The region between the dotted-dashed line and the periphery of the first IC die 120a in FIGS. 14A and 14B schematically illustrates the “keep-out-zone” 160 (KOZ) of the first IC die 120a. The KOZ 160 is a region of the IC die 120 (or of the UAs in the semiconductor wafer 100 prior to singulation) that is not usable for forming device structures due to thermal management components, cooling, and mounting constraints. The KOZ 160 is typically located around the periphery of the IC die 120, as shown in FIGS. 14A and 14B. In various embodiments, it may be advantageous to utilize one or more protective films 150 over surfaces of the IC dies 120, such as over the side surfaces 124 of the IC dies 120 and within the bay regions 126, when the KOZ 160 of the IC die 120 is relatively small. This may help to avoid cracks that extend into the portion of the IC die 120 including device structures which may be damaged by the cracks. In contrast, when the KOZ 160 of the IC die 120 is large, crack formation may be confined to the KOZ 160 of the IC die 120 such that device structures may not be damaged. In such cases, a protective film 150 may be omitted in some embodiments. In some embodiments, one or more protective films 150 may be utilized when the KOZ 160 of the IC die 120 is ≤ 20 μm. In embodiments in which the KOZ 160 is >20 μm, a protective film 150 may not be utilized in some cases. The protective films 150 may be applied before the IC dies 120a, 120b are bonded over a carrier structure 140 to form a bonded device structure 130 or may be applied after the IC dies 120a, 120b are bonded over the carrier structure 140 to form the bonded device structure 130.

FIG. 14C is an enlarged vertical cross-section view of region D of FIG. 14A illustrating a single protective film 150 over the first IC die 120a. FIG. 14D is an enlarged vertical cross-section view of region D of FIG. 14A illustrating an alternative embodiment in which a first protective film 150a, a second protective film 150b, and a third protective film 150c are located over the first IC die 120a. The materials of the first protective film 150a, the second protective film 150b, and a third protective film 150c may be the same or may be different. In some embodiments, the material(s) of the protective film(s) 150 may be selected based on their compatibility with the molding portion 151 formed over the protective film(s) 150. In some embodiments, a single protective film 150 may be preferable when the aspect ratio (W/H) of the bay region 126 is relatively large, while multiple (e.g., two or three) protective films 150 may be utilized when the aspect ratio of the bay region 126 is relatively small. In some embodiments, a total thickness of the protective film(s) 150 may be less than one-half of the vertical inner height dimension, H₁, of the bay region 126.

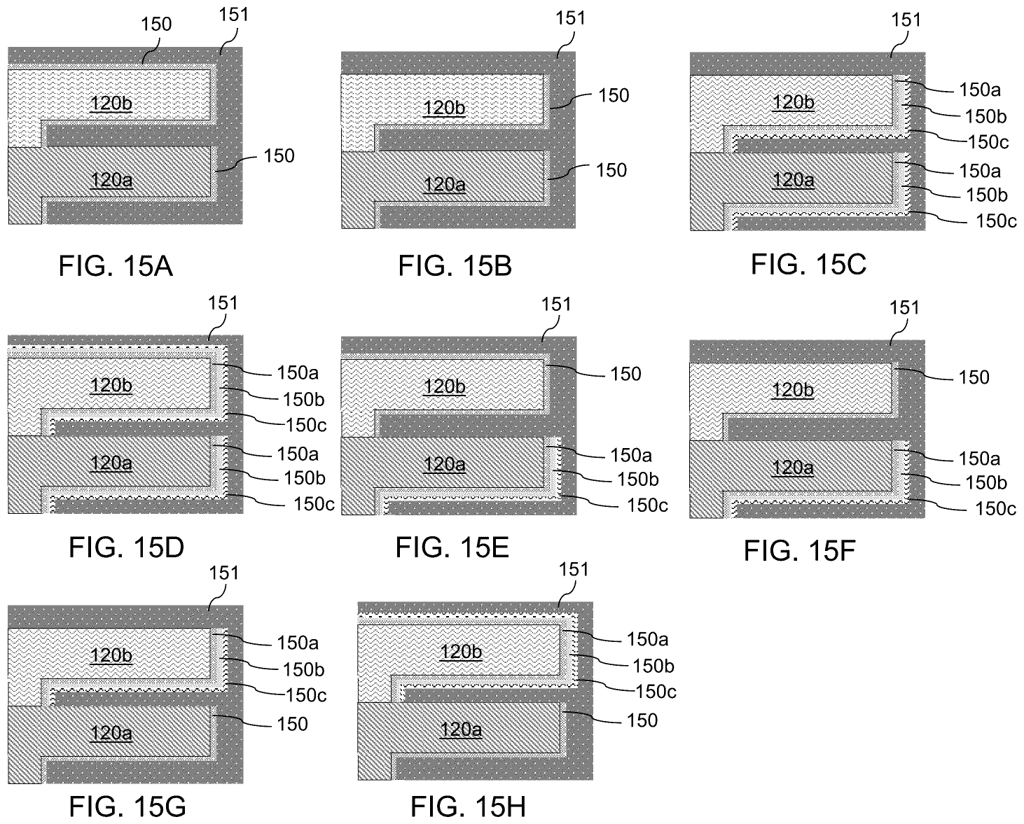

FIGS. 15A-15H are vertical cross-section views of multi-tiered bonded device structures 130 illustrating different configurations of protective films 150 according to various embodiments of the present disclosure. FIG. 15A illustrates an embodiment in which a single protective film 150 is located over both a first IC die 120a in a first tier and a second IC die 120b in a second tier. The protective film 150 is located over the side surfaces 124 and within the bay region 126 of the first IC die 120a, but is not present over the upper surface of the first IC die 120a. In contrast, the protective film 150 is located over the side surfaces 124, within the bay region 126, and over the upper surface of the second IC die 120b. FIG. 15B illustrates an embodiment that is similar to the embodiment of FIG. 15A, except that the protective film 150 is not located over the upper surface of the second IC die 120b.

FIG. 15C illustrates an embodiment in which a first protective film 150a, a second protective film 150b and a third protective film 150c are located over the first IC die 120a and the second IC die 120b. The first protective film 150a, the second protective film 150b and the third protective film 150c are each located over the side surfaces 124 and within the bay regions 126 of the first IC die 120a and the second IC die 120b, but are not located over the upper surfaces of either the first IC die 120a or the second IC die 120b. FIG. 15D illustrates a similar configuration except that in FIG. 15D, the first protective film 150a, the second protective film 150b and the third protective film 150c are each located over the upper surface of the second IC die 120b.

FIG. 15E illustrates an embodiment in which a first protective film 150a, a second protective film 150b and a third protective film 150c are located over the first IC die 120a, and a single protective film 150 is located over the second IC die 120b. In this embodiment, the first protective film 150a, the second protective film 150b and the third protective film 150c are located over the side surfaces and within the bay region of the first IC die 120a but are not located over the upper surface of the first IC die 120. The single protective film 150 is located over the side surfaces, within the bay regions, and over the upper surface of the second IC die 120b. FIG. 15F illustrates yet another embodiment that is similar to FIG. 15E except that in the FIG. 15F embodiment, the protective film 150 is not present over the upper surface of the second IC die 120b.

FIGS. 15G and 15H illustrate embodiments in which a single protective film 150 is located over the first IC die 120a, and the first protective film 150a, the second protective film 150b and the third protective film 150c are located over the second IC die 120b. In both FIGS. 15G and 15H, the single protective film 150 is located over the side surfaces and within the bay region of the first IC die 120a but is not located over the upper surface of the first IC die 120a. In the embodiment shown in FIG. 15G, the first protective film 150a, the second protective film 150b and the third protective film 150c are each located over the side surfaces and within the bay region of the second IC die 120b but are not located over the upper surface of the second IC die 120b. In the embodiment shown in FIG. 15H, the first protective film 150a, the second protective film 150b and the third protective film 150c are also located over the upper surface of the second IC die 120b.

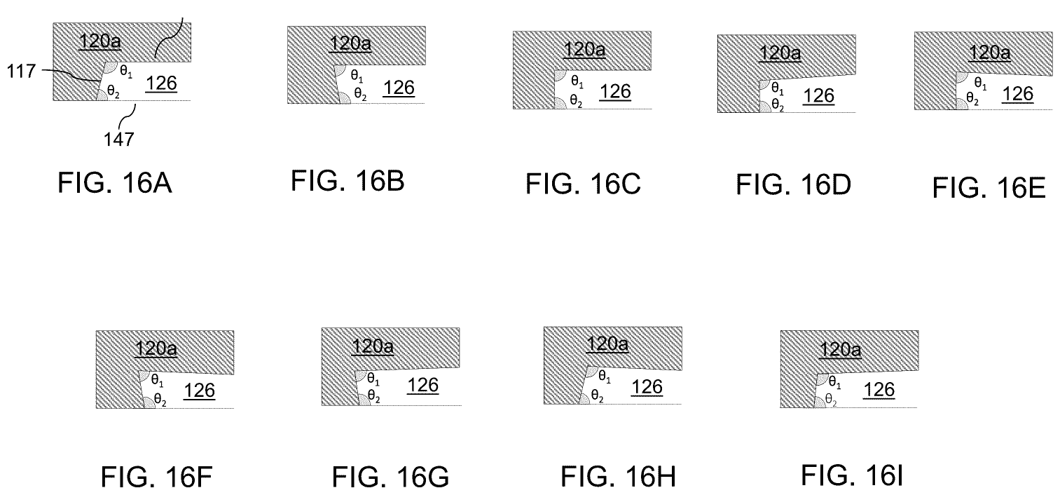

FIGS. 16A-16I are vertical cross-section views of bonded device structures 130 illustrating different shapes of the bay regions 126 underlying the eaves 121 according to various embodiments of the present disclosure. The shapes of the bay regions 126 may be defined, in part, by the angle, θ₁, between the interior sidewall 117 and the top surface 118 of the bay region 126, and the angle, θ₂, between the interior sidewall 117 and the bottom surface 147 of the bay region 126. Differences in these angles θ₁ and θ₂ may produce differently-shaped bay regions 126 when viewed in vertical cross-section. FIGS. 16A-16C illustrate embodiments where the sum of angles θ₁ and θ₂ is equal to 180°. In such cases, the top surface 118 and the bottom surface 147 of the bay region 126 are parallel to one another, and the bay region 126 may have a truncated parallelogram shape. FIG. 16A illustrates an example where θ₁>θ₂, and FIG. 16B illustrates an example where θ₁<θ₂. FIG. 16C illustrates the case where θ₁=θ₂ (i.e., θ₁ and θ₂ are both) 90°, in which case the bay region 126 has a rectangular shape.

FIGS. 16D-16I illustrate examples where the top surface 118 and the bottom surface 147 of the bay region 126 are not parallel, and the bay region 126 has an irregular polygon shape. FIGS. 16D and 16E illustrate examples of bay regions 126 having an irregular polygon shape where θ₂=90°, 0°<θ₁<180°, and θ₁≠θ₂. FIG. 16E illustrates an example where θ₁>90°, and FIG. 16E illustrates an example where θ₁<90°.

FIGS. 16F and 16G illustrate examples of bay regions 126 having an irregular polygon shape where θ₂>90°, 0°<θ₁<180°, and θ₁+θ₂/180. FIG. 16F illustrates an example where θ₁<90°, and FIG. 16G illustrates an example where θ₁>90°.

FIGS. 16H and 16I illustrate examples of bay regions 126 having an irregular polygon shape where θ₂<90°, 0°<θ₁<180°, and θ₁+θ₂/180. FIG. 16H illustrates an example where θ₁<90°, and FIG. 16I illustrates an example where θ₁>90°.

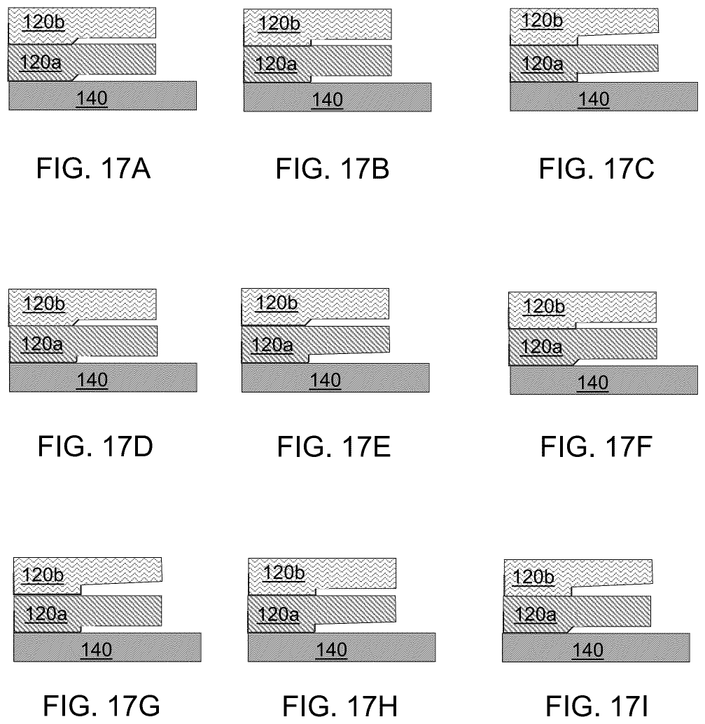

In a multi-tiered bonded device structure 130 as described above, the different IC dies 120a, 120b may include bay regions 126 having the same or different shapes. FIGS. 17A-17I are vertical cross-section views of multi-tiered bonded device structures 130 illustrating various configurations of the shapes of the bay regions 126 for the IC dies 120a, 120b in different tiers according to various embodiments of the present disclosure. FIGS. 17A-17C illustrate examples where a first IC die 120a in a first tier and a second IC die 120b in a second tier include bay regions 126 having the same type of shapes. FIG. 17A illustrates an example where both bay regions 126 have a truncated parallelogram shape. FIG. 17B illustrates an example where both bay regions 126 have a rectangular shape. FIG. 17C illustrates an example where both bay regions 126 have an irregular polygon shape.

FIGS. 17D-17I illustrate examples where a first IC die 120a in a first tier and a second IC die 120b in a second tier include bay regions 126 having different types of shapes. FIG. 17D illustrates an example where the bay region 126 of the first IC die 120a has a rectangular shape and the bay region 126 of the second IC die 120b has a truncated parallelogram shape. FIG. 17E illustrates an example where the bay region 126 of the first IC die 120a has an irregular polygon shape and the bay region 126 of the second IC die 120b has a truncated parallelogram shape. FIG. 17F illustrates an example where the bay region 126 of the first IC die 120a has a truncated parallelogram shape and the bay region 126 of the second IC die 120b has a rectangular shape. FIG. 17G illustrates an example where the bay region 126 of the first IC die 120a has a rectangular shape and the bay region 126 of the second IC die 120b has an irregular polygon shape. FIG. 17H illustrates an example where the bay region 126 of the first IC die 120a has an irregular polygon shape and the bay region 126 of the second IC die 120b has a rectangular shape. FIG. 17I illustrates an example where the bay region 126 of the first IC die 120a has a truncated parallelogram shape and the bay region 126 of the second IC die 120b has an irregular polygon shape.

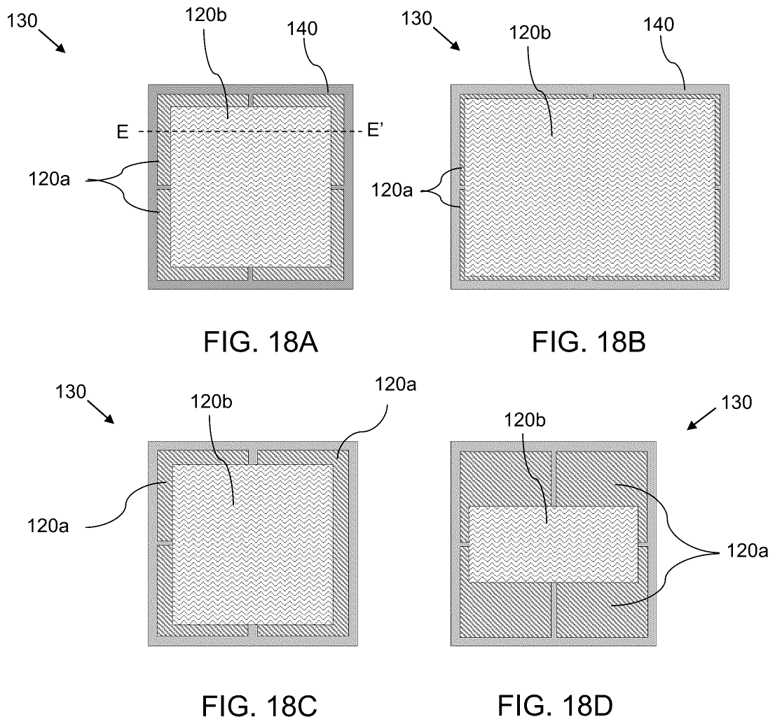

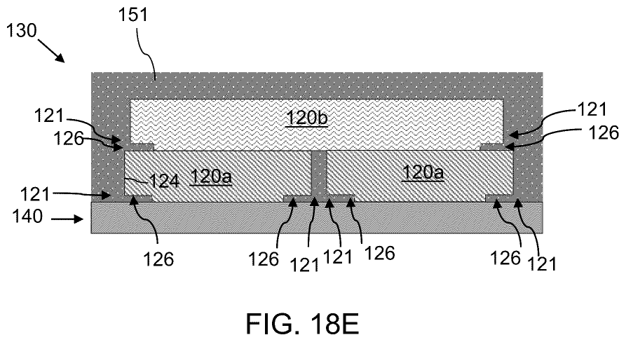

FIGS. 18A-18D are top views of bonded device structures 130 according to various embodiments of the present disclosure. Referring to FIGS. 18A-18D, in some embodiments, one or more tiers of a multi-tier bonded device structure 130 may include multiple IC dies 120. For example, a first tier may include a plurality of first IC dies 120a bonded to the carrier structure 140. The plurality of first IC dies 120a may be laterally spaced from one another, and an above-described molding portion 151 may be located between adjacent first IC dies 120a. One or more second IC dies 120b may be bonded over the plurality of first IC dies 120b to form a second tier. A molding portion 151 may laterally surround each of the one or more second IC dies 120b. Additional IC dies 120 may optionally be bonded over the one or more second IC dies 120b to form additional tiers of the bonded device structure 130.

FIGS. 18A-18D illustrate exemplary configurations of a bonded device structure 130 having two tiers. For clarity of illustration, the molding portion 151 is omitted from FIGS. 18A-18D. Referring to FIG. 18A, the bonded device structure 130 may include four square-shaped first IC dies 120a having identical sizes bonded to the carrier structure 140 to form a first tier. A single square-shaped second IC die 120b having a size that is larger than the sizes of the first IC dies 120a may be bonded over and may partially overlie each of the first IC dies 120a to form a second tier. FIG. 18E is a vertical cross-section view of the bonded device structure 130 of FIG. 18A taken along line E-E′ in FIG. 18A. As shown in FIGS. 18A and 18E, in some embodiments, the sidewall(s) of the second IC die 120b may not be vertically aligned with the corresponding sidewall(s) of the underlying first IC dies 120a. In some embodiments, the sidewalls of the second IC die 120b may be laterally offset from the outer sidewalls of the first IC dies 120a (i.e., the sidewalls that do not face towards an adjacent first IC die 120a) such that the eaves 121 of the second IC die 120b do not extend to or beyond the outer sidewalls of the underlying first IC dies 120a. In other embodiments, the sidewalls of the second IC die 120b may be vertically aligned with the outer sidewalls of the underlying first IC dies 120a or may extend beyond the outer sidewalls of the underlying first IC dies 120a. FIG. 18B illustrates a similar configuration in which the first IC dies 120a and the second IC die 120b each have a rectangular shape.

FIG. 18C illustrates a bonded device structure 130 including three first IC dies 120a bonded to the carrier structure 140 to form a first tier. The first IC dies 120a includes a pair of square shaped first IC dies 120a located on one side of the carrier structure 140 and a larger rectangular shaped first IC die 120a located on the other side of the carrier structure 140. A single square-shaped second IC die 120b is bonded over and partially overlies each of the first IC dies 120a to form a second tier.

FIG. 18D illustrates a bonded device structure 130 including four square-shaped first IC dies 120a having identical sizes bonded to the carrier structure 140 to form a first tier. A single rectangular-shaped second IC die 120b is bonded over and partially overlies each of the first IC dies 120a to form a second tier.

Various other arrangements for a multi-tiered bonded device structure 130 may be utilized. For example, although the embodiments shown in FIGS. 18A-18D illustrate a first tier including multiple first IC dies 120a and a second tier including a single second IC die 120b, in other embodiments, the first tier may include a single first IC die 120a and the second tier may include multiple second IC dies 120b, or both the first and second tier may include multiple IC dies 120a, 120b.

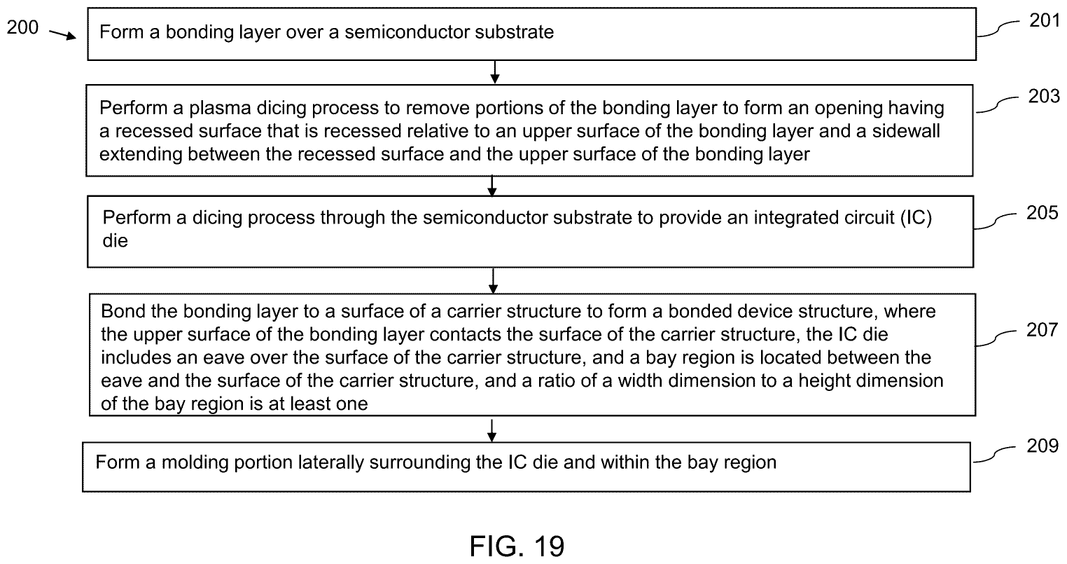

FIG. 19 is a flowchart illustrating a method 200 of fabricating a bonded device structure 130 according to an embodiment of the present disclosure. Referring to FIGS. 1, 2, and 19, in step 201 of method 200, a first bonding layer 109 may be formed over a semiconductor substrate 101. Referring to FIGS. 3, 4, and 19, in step 203 of method 200 a plasma dicing process may be performed to remove portions of the first bonding layer 109 to form an opening 115 having a recessed surface 118 that is recessed relative to a planar upper surface 112 of the first bonding layer 109 and an interior sidewall 117 extending between the recessed surface 118 and the planar upper surface 112 of the first bonding layer 109. Referring to FIGS. 6, 7, and 19, in step 205 of method 200, a dicing process may be performed through the semiconductor substrate 101 to provide an IC die 120. Referring to FIGS. 8, 13A, 13B and 19, in step 207 of method 200, the first bonding layer 109 may be bonded to a surface 147 of a carrier structure 140 to form a bonded device structure 130, where the planar upper surface 112 of the first bonding layer 109 contacts the surface 147 of the carrier structure 140, the IC die 120 includes an eave 121 over the surface 147 of the carrier structure 140, and a bay region 126 is located between the eave 121 and the surface 147 of the carrier structure 140, and a ratio of a width dimension W to a height dimension H of the bay region 126 is at least one. Referring to FIGS. 11, 13A, 13C and 19, in step 209, a molding portion 151 may be formed laterally surrounding the IC die 120 and within the bay region 126.

Referring to all drawings and according to various embodiments of the present disclosure, a bonded device structure 130 includes a carrier structure 140, an integrated circuit (IC) die 120 bonded to a surface 147 of the carrier structure 140 via a first bonding layer 109, the IC die 120 including an eave 121 over the surface 147 of the carrier structure 140, wherein a bay region 126 is located between the eave 121 and the surface 147 of the carrier structure 140, and a ratio of a width dimension W to a height dimension H of the bay region 126 is at least one, and a molding portion 151 laterally surrounding the IC die 120 and located within the bay region 126 between the surface 147 of the carrier structure 140 and the eave 121.

In one embodiment, the bay region 126 is located between a lower surface 118 of the eave 121, the surface 147 of the carrier structure, and an interior sidewall 117 extending between the lower surface 118 of the eave 121 and the surface 147 of the carrier structure 140.

In another embodiment, the width dimension W of the bay region 126 is equal to an average of horizontal width dimensions (W1, W2) of the bay region 126 along the top and bottom surfaces (118, 147) of the bay region 126, and the height dimension H of the bay region is equal to an average of vertical height dimensions (H1, H2) of the bay region on inner and outer sides of the bay region, and where the ratio of the width dimension W to the height dimension H of the bay region is equal to or less than 80.

In another embodiment, a first angle θ1 between the interior sidewall 117 and the lower surface 118 of the eave 121 is between 10° and 170° and a second angle θ2 between the interior sidewall 117 and the surface 147 of the carrier structure 140 is between 10° and 170°.

In another embodiment, the horizontal width dimension W1 of the bay region 126 along the top surface 118 of the bay region 126 is equal to or less than 100 μm, the horizontal width dimension W2 of the bay region 126 along the bottom surface 147 of the bay region 126 is between 0.5 and 1.5 times the horizontal width dimension W1 of the bay region 126 along the top surface 118 of the bay region 126, and the vertical height dimension H1 of the bay region 126 on the inner side of the bay region 126 is equal to or greater than 1 μm.

In another embodiment, the IC die 120 has a thickness dimension T along a side surface 124 of the IC die 120, a horizontal width dimension W of the eave is greater than 1/100th of the thickness dimension T of the IC die 120, and the vertical height dimension H1 of the bay region on the inner side of the bay region 126 is greater than 1/200th of the thickness dimension T of the IC die 120 and less than ½ of the thickness dimension T of the IC die 120.

In another embodiment, the bay region 126 has a rectangular, truncated parallelogram, or irregular polygon shape in a vertical cross-section.

In another embodiment, the bonded device structure 130 further includes at least one protective film 150 over a side surface 124 of the IC die and within the bay region 126 over the bottom surface 118 of the eave 121 and the interior sidewall 117, and the at least one protective film 150 is located between IC die 120 and the molding portion 151.

In another embodiment, a ratio of a total volume of voids 155 in the molding portion 151 to a total volume of molding compound in the molding portion 151 is between 0.2 and 0.4.

In another embodiment, the IC die 120 includes a logic die, a memory die, an analog die, an RF die, an integrated passive device (IPD) die, or a dummy die, and the carrier structure 140 includes a substrate, an interposer, a semiconductor die, or a semiconductor wafer.

In another embodiment, the first bonding layer 109 of the IC die 120 includes a plurality of first metal bonding pads 111 formed within a dielectric material layer 108 and the first bonding layer 109 of the IC die 120 is bonded to a corresponding bonding layer 141 of the carrier structure 140 via a metal-to-metal and dielectric-to-dielectric direct bond.

In another embodiment, the IC die includes a first IC die 120a, and the bonded device structure 130 further includes a second IC die 120b bonded over the first IC die 120a, the second IC die 120b including an eave 121 and a bay region 126 underlying the eave 121, and a ratio of a width dimension W to a height dimension H of the bay region 126 underlying the eave 121 of the second IC die 120b is at least one, and the molding portion 151 laterally surrounds the second IC die 120b and is located within the bay region 126 underlying the eave 121 of the second IC die 120b.

Another embodiment is drawn to a bonded device structure 130 including a carrier structure 140, at least one integrated circuit (IC) die 120 bonded to a surface 147 of the carrier structure 140 via a first bonding layer 109, each IC die 120 including an eave 121 over the surface 147 of the carrier structure 140, where a bay region 126 is located between the eave 121 and the surface 147 of the carrier structure 140, and a molding portion 151 laterally surrounding the IC die 120 and located within the bay region 126 between the surface 147 of the carrier structure 140 and the eave 121, and a ratio of a total volume of voids 155 in the molding portion 151 to a total volume of molding compound in the molding portion 151 is between 0.2 and 0.4.

In one embodiment, the bonded device structure 130 includes a multi-tier bonded device structure 130 including a plurality of IC dies 120, wherein one or more first IC dies 120a bonded to the surface 147 of the carrier structure 140 form a first tier of IC dies and one or more second IC dies 120b bonded over the first IC dies 120a form a second tier of IC dies, each of the first IC dies 120a and the second IC dies 120b including an eave 121 with a bay region 126 underlying the eave 121, and the molding portion 151 laterally surrounds each of the first IC dies 120a and the second IC dies 120b and is located within each of the bay regions 126 underlying the eaves 121 of the first IC dies 120a and the second IC dies 120b.

In another embodiment, a protective film 150 is provided over surfaces of each IC die (120a, 120b) having a keep-out-zone of 20 μm or less.

In another embodiment, the bay regions 126 underlying the eaves of the one or more first IC dies 120a and the one or more second IC dies 120b have non-uniform shapes.

Another embodiment is drawn to a method of fabricating a bonded device structure 130 that includes forming a first bonding layer 109 over a semiconductor substrate 101, performing a plasma dicing process to remove portions of the first bonding layer 109 and form an opening 115 having a recessed surface 118 that is recessed relative to a planar upper surface 112 of the bonding layer 109 and an interior sidewall 117 extending between the recessed surface 118 and a planar upper surface 112 of the bonding layer, performing a dicing process through the semiconductor substrate 101 to provide an integrated circuit die 120, bonding the first bonding layer 109 to a surface 147 of a carrier structure 140 to form a bonded device structure 130, where the planar upper surface 112 of the bonding layer 109 contacts the surface 147 of the carrier structure 140, the IC die 120 includes an eave 121 over the surface of the carrier structure 140, and a bay region 126 is located between the eave 121 and the surface 147 of the carrier structure 140, and a ratio of a width dimension W to a height dimension H of the bay region 126 is at least one, and forming a molding portion 151 laterally surrounding the IC die 120 and within the bay region 126.

In one embodiment, forming the molding portion 151 includes controlling a curing temperature and a heating rate of a molding process such that a ratio of a total volume of voids 155 in the molding portion 151 to a total volume of molding compound in the molding portion 151 is between 0.2 and 0.4.

In another embodiment, the method further includes performing a laser grooving process to form a groove 119 around the periphery of the IC die 120 prior to performing the dicing process through the semiconductor substrate 101, where following the laser grooving process, at least a portion of the recessed surface 118 remains between the groove 119 and the interior sidewall 117.

In another embodiment, the first bonding layer 109 includes a first bonding layer 109 having a plurality of first metal bonding pads 111 laterally surrounded by a dielectric material layer 108, and where bonding the first bonding layer 109 to the surface 147 of the carrier structure 140 includes bringing the IC die 120 into contact with the carrier structure 140 such that the planar upper surface 112 of the first bonding layer 109 contacts a second bonding layer 141 on the carrier structure 140, where each of the first metal bonding pads 111 of the first bonding layer 109 contacts a corresponding bonding pad 142 of the second bonding layer 141, and performing an annealing process to promote interdiffusion between the bonding pads 111 of the first bonding layer 109 and the corresponding bonding pads 142 of the second bonding layer 141.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A bonded device structure, comprising:
a carrier structure;
an integrated circuit (IC) die bonded to a surface of the carrier structure via a bonding layer, the IC die comprising an eave over the surface of the carrier structure, wherein a bay region is located between the eave and the surface of the carrier structure, and a ratio of a width dimension to a height dimension of the bay region is at least one; and
a molding portion laterally surrounding the IC die and located within the bay region between the surface of the carrier structure and the eave.

2. The bonded device structure of claim 1, wherein the bay region is located between a lower surface of the eave, the surface of the carrier structure, and a sidewall extending between the lower surface of the eave and the surface of the carrier structure.

3. The bonded device structure of claim 2, wherein the width dimension of the bay region is equal to an average of horizontal width dimensions of the bay region along a top surface of the bay region and a bottom surface of the bay region, and the height dimension of the bay region is equal to an average of vertical height dimensions of the bay region on inner and outer sides of the bay region, and wherein the ratio of the width dimension to the height dimension of the bay region is equal to or less than 80.

4. The bonded device structure of claim 3, wherein a first angle between the sidewall and the lower surface of the eave is between 10° and 170° and a second angle between the sidewall and the surface of the carrier structure is between 10° and 170°.

5. The bonded device structure of claim 3, wherein the horizontal width dimension of the bay region along the top surface of the bay region is equal to or less than 100 μm, the horizontal width dimension of the bay region along the bottom surface of the bay region is between 0.5 and 1.5 times the horizontal width dimension of the bay region along the top surface of the bay region, and the vertical height dimension of the bay region on the inner side of the bay region is equal to or greater than 1 μm.

6. The bonded device structure of claim 3, wherein the IC die comprises a thickness dimension along a side surface of the IC die, a horizontal width dimension of the eave is greater than 1/100th of the thickness dimension of the IC die, and the vertical height dimension of the bay region on the inner side of the bay region is greater than 1/200th of the thickness dimension of the IC die and less than ½ of the thickness dimension of the IC die.

7. The bonded device structure of claim 1, wherein the bay region has a rectangular, truncated parallelogram, or irregular polygon shape in a vertical cross-section.

8. The bonded device structure of claim 2, further comprising at least one protective film over a side surface of the IC die and within the bay region over the lower surface of the eave and the sidewall, and the at least one protective film is located between IC die and the molding portion.

9. The bonded device structure of claim 1, wherein a ratio of a total volume of voids in the molding portion to a total volume of molding compound in the molding portion is between 0.2 and 0.4.

10. The bonded device structure of claim 1, wherein the IC die comprises a logic die, a memory die, an analog die, an RF die, an integrated passive device (IPD) die, or a dummy die, and the carrier structure comprises a substrate, an interposer, a semiconductor die, or a semiconductor wafer.

11. The bonded device structure of claim 1, wherein the bonding layer of the IC die comprises a plurality of bonding pads embedded in a dielectric material and the bonding layer of the IC die is bonded to a corresponding bonding layer of the carrier structure via a metal-to-metal and dielectric-to-dielectric direct bond.

12. The bonded device structure of claim 1, wherein the IC die comprises a first IC die, and the bonded device structure further comprises a second IC die bonded over the first IC die, the second IC die comprising an eave and a bay region underlying the eave, and a ratio of a width dimension to a height dimension of the bay region underlying the eave of the second IC die is at least one, and the molding portion laterally surrounds the second IC die and is located within the bay region underlying the eave of the second IC die.

13. A bonded device structure, comprising:
a carrier structure;
at least one integrated circuit (IC) die bonded to a surface of the carrier structure via a bonding layer, each IC die comprising an eave over the surface of the carrier structure, wherein a bay region is located between the eave and the surface of the carrier structure; and
a molding portion laterally surrounding each IC die and located within the bay region between the surface of the carrier structure and the eave of each IC die, and a ratio of a total volume of voids in the molding portion to a total volume of molding compound in the molding portion is between 0.2 and 0.4.

14. The bonded device structure of claim 13, wherein the bonded device structure comprises a multi-tier bonded device structure comprising a plurality of IC dies, wherein one or more first IC dies bonded to the surface of the carrier structure form a first tier of IC dies and one or more second IC dies bonded over the first IC dies form a second tier of IC dies, each of the first IC dies and the second IC dies comprising an eave with a bay region underlying the eave, and the molding portion laterally surrounds each of the first IC dies and the second IC dies and is located within each of the bay regions underlying the eaves of the first IC dies and the second IC dies.

15. The bonded device structure of claim 14, wherein a protective film is provided over surfaces of each IC die having a keep-out-zone of 20 μm or less.

16. The bonded device structure of claim 14, wherein the bay regions underlying the eaves of the one or more first IC dies and the one or more second IC dies have non-uniform shapes.

17. A method of fabricating a bonded device structure, comprising:
forming a bonding layer over a semiconductor substrate;
performing a plasma dicing process to remove portions of the bonding layer and form an opening having a recessed surface that is recessed relative to an upper surface of the bonding layer and a sidewall extending between the recessed surface and an upper surface of the bonding layer;
performing a dicing process through the semiconductor substrate to provide an integrated circuit (IC) die;
bonding the bonding layer to a surface of a carrier structure to form a bonded device structure, wherein the upper surface of the bonding layer contacts the surface of the carrier structure, the IC die comprises an eave over the surface of the carrier structure, and a bay region is located between the eave and the surface of the carrier structure, and a ratio of a width dimension to a height dimension of the bay region is at least one; and
forming a molding portion laterally surrounding the IC die and within the bay region.

18. The method of claim 17, wherein forming the molding portion comprises controlling a curing temperature and a heating rate of a molding process such that a ratio of a total volume of voids in the molding portion to a total volume of molding compound in the molding portion is between 0.2 and 0.4.

19. The method of claim 17, further comprising:
performing a laser grooving process to form a groove around the periphery of the IC die prior to performing the dicing process through the semiconductor substrate, wherein following the laser grooving process, at least a portion of the recessed surface remains between the groove and the sidewall.

20. The method of claim 17, wherein the bonding layer comprises a first bonding layer comprising a plurality of bonding pads laterally surrounded by a dielectric material, and wherein bonding the first bonding layer to the surface of the carrier structure comprises:
bringing the IC die into contact with the carrier structure such that the upper surface of the bonding layer contacts a second bonding layer on the carrier structure, where each of the plurality of bonding pads of the first bonding layer contacts a corresponding bonding pad of the second bonding layer; and
performing an annealing process to promote interdiffusion between the bonding pads of the first bonding layer and the corresponding bonding pads of the second bonding layer.
